(19) United States
(12) Patent Application Publication
(10) Pub. No.: US 2015/0076644 A1
(43) Pub. Date: Mar. 19, 2015

(54) METHOD FOR MANUFACTURING SOLID-STATE IMAGE SENSOR

(71) Applicant: CANON KABUSHIKI KAISHA, Tokyo (JP)

(72) Inventor: Masaki Kurihara, Koza-gun (JP)

(21) Appl. No.: 14/476,986

(22) Filed: Sep. 4, 2014

(30) Foreign Application Priority Data
Sep. 18, 2013 (JP) 2013-193486

(51) Int. Cl. H01L 27/146

(52) U.S. Cl. CPC H01L 27/14685; H01L 27/14689; H01L 27/14625
USPC 257/432; 438/69

(57) ABSTRACT

A method for manufacturing a solid-state image sensor, comprising preparing a substrate including a pixel region where a plurality of pixels are provided and a peripheral region, forming a structure including a wiring layer and an interlayer insulation film on the pixel region and the peripheral region, forming a first wiring pattern only on the structure located in the peripheral region, forming a protective film covering the first wiring pattern and the structure, forming a second wiring pattern on a convex portion of the protective film formed by steps between an upper surface of the first wiring pattern and the structure so that an end of the second wiring pattern is located away from the pixel region than an end of the first wiring pattern in a state that the protective film covers the first wiring pattern, and forming an optical system.

### BACKGROUND OF THE INVENTION

1. Field of the Invention

The present invention relates to a method for manufacturing a solid-state image sensor.

2. Description of the Related Art

A solid-state image sensor can employ a recess structure in which the upper surface of a portion including a wiring pattern and an interlayer insulation film provided on a substrate is higher in a region immediately above the peripheral portion of a pixel array than in a region immediately above the pixel array, and have steps (a height difference) on the upper surface. In the process of manufacturing the solid-state image sensor, this height difference may cause stripes and unevenness (so-called striations) in a film formed by spin coating. Hence, it is not preferable to locally form such height difference.

Japanese Patent Laid-Open No. 2008-270500 discloses a recess structure in which a stepwise height difference including a plurality of steps is provided so as not to locally form a height difference on an upper surface. According to Japanese Patent Laid-Open No. 2008-270500, when a wiring pattern and an interlayer insulation film are formed on a substrate, a plurality of wiring patterns are provided in advance on the above-described peripheral portion such that a distance from the boundary between a pixel array and its peripheral portion becomes larger in an upper layer than in a lower layer. That is, the plurality of wiring patterns are formed such that an opening increases in size from the lower layer to the upper layer. After that, etching is performed on an insulation member immediately above the pixel array, thereby forming the recess structure. When the etching is performed, each of the plurality of wiring patterns described above is used as an etching mask. As a result of removing the portion of the insulation member which is not covered by each wiring pattern, the recess structure having the stepwise height difference on the upper surface is formed.

However, according to this method, the upper surface of each wiring pattern suffers damage by etching. This may cause a loss in quality of the solid-state image sensor.

### SUMMARY OF THE INVENTION

The present invention provides a technique advantageous in improving the quality of a solid-state image sensor with a recess structure.

One of the aspects of the present invention provides a method for manufacturing a solid-state image sensor, comprising preparing a substrate including a pixel region where a plurality of pixels are provided and a peripheral region located outside the pixel region, forming a structure including a wiring layer and an interlayer insulation film on the pixel region and the peripheral region of the substrate, forming a first wiring pattern only on the structure located in the peripheral region, forming a protective film covering the first wiring pattern and the structure, forming a second wiring pattern on a convex portion of the protective film, the convex portion formed by steps between an upper surface of the first wiring pattern and an upper surface of the structure, so that an end of the second wiring pattern is located away from the pixel region than an end of the first wiring pattern in a state in which the protective film covers the first wiring pattern, and forming an optical member on the structure of the pixel region.

Further features of the present invention will become apparent from the following description of exemplary embodiments with reference to the attached drawings.

### BRIEF DESCRIPTION OF THE DRAWINGS

FIG. 1 is a view for explaining an example of the arrangement of a solid-state image sensor;

FIGS. 2A to 2I are views for explaining an example of a method for manufacturing the solid-state image sensor;

FIGS. 3A to 3I are views for explaining another example of a method for manufacturing a solid-state image sensor;

FIGS. 4A to 4J are views for explaining still another example of a method for manufacturing a solid-state image sensor;

FIGS. 5A to 5J are views for explaining still another example of a method for manufacturing a solid-state image sensor; and

FIGS. 6A to 6D are views for explaining another example of the arrangement of a solid-state image sensor.

### DESCRIPTION OF THE EMBODIMENTS

### First Embodiment

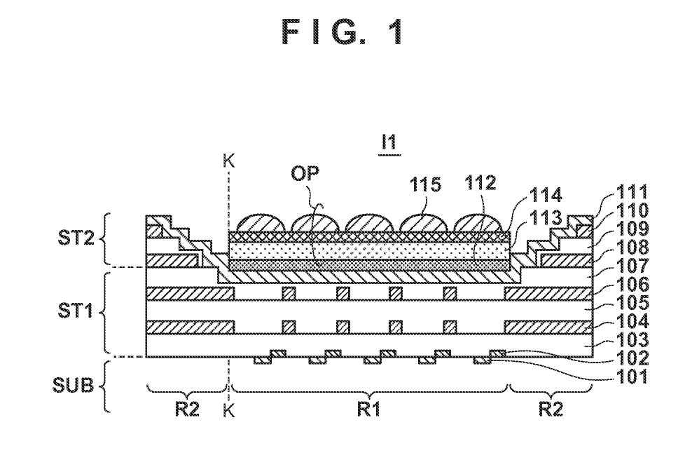

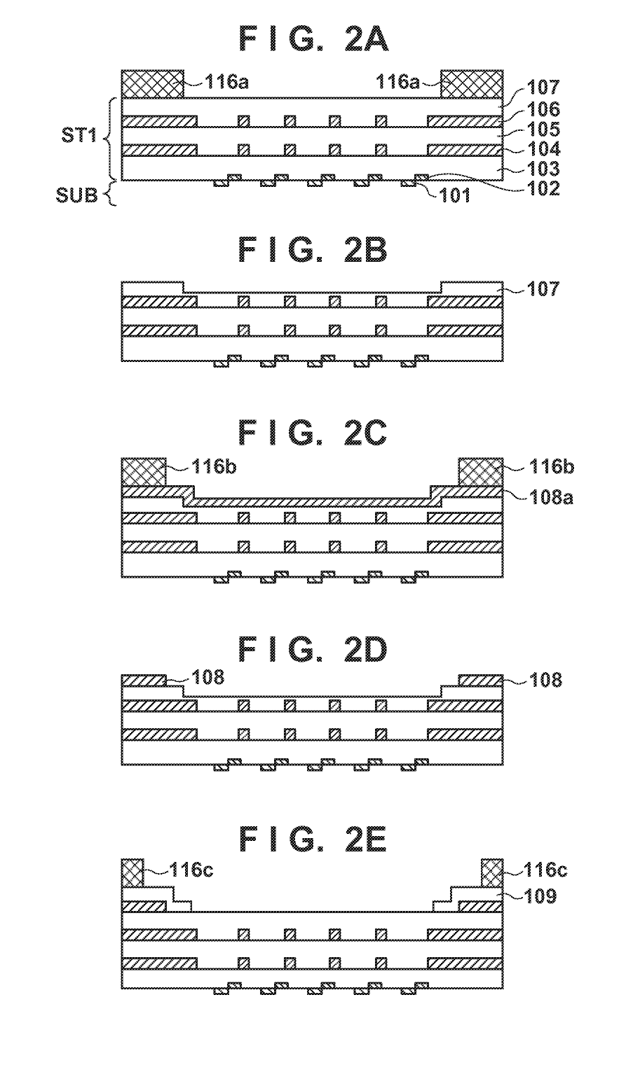

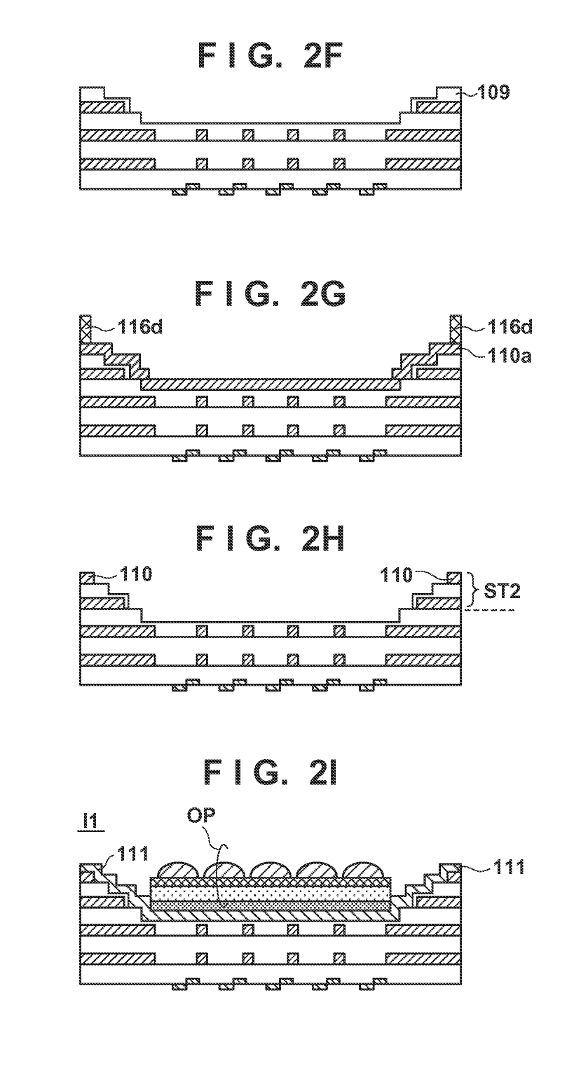

A method for manufacturing a solid-state image sensor I1 according to the first embodiment will be described with reference to FIG. 1 and FIGS. 2A to 2I. FIG. 1 schematically illustrates an example of the sectional structure of the solid-state image sensor I1. The solid-state image sensor I1 can include a substrate SUB including a pixel region R1 and a peripheral region R2, a structure ST1 provided on the substrate SUB, a structure ST2 provided on the structure ST1, and an optical system OP made of optical members.

A pixel array in which a plurality of pixels are arrayed is formed in the pixel region R1. In the pixel region R1, photoelectric conversion portions 101, and (the gates of) transistors 102 configured to read out charges generated and accumulated in the photoelectric conversion portions 101 as pixel signals are illustrated as the components of the respective pixels. The components of the respective pixels represent elements provided on the substrate SUB below. The peripheral region R2 is a region peripheral to the pixel region R1. For example, a driving unit configured to drive the respective pixels and a processor configured to process the pixel signals read out from the respective pixels can be arranged in the peripheral region R2.

The peripheral region R2 is located outside the pixel region R1 on the substrate SUB. The number of layers of a wiring pattern provided in the peripheral region R2 is larger than that in the pixel region R1. A boundary K between the pixel region R1 and the peripheral region R2 can be decided by, for example, the end of the wiring pattern which has more layers than in the pixel region R1. Also, the peripheral region R2 may include an optical black pixel region where, for example, wiring patterns for light-shielding (light-shielding patterns) are provided more than effective pixels that light can enter.

The structure ST1 includes wiring layers and interlayer insulation films. In the structure ST1, interlayer insulation films 103, 105, and 107, the first wiring layer which includes a wiring pattern 104 provided between the interlayer insulation films 103 and 105, and the second wiring layer which includes a wiring pattern 106 provided between the interlayer insulation films 105 and 107 are illustrated.

The structure ST2 can be provided above the peripheral region R2, and include wiring patterns 108 and 110, and an insulation member 109 (interlayer insulation film) provided between the wiring patterns 108 and 110. In a planar view, the distance from the boundary K between the pixel region R1 and the peripheral region R2 to the end portion of the wiring pattern 110 is larger than the distance from the boundary K to the end portion of the wiring pattern 108. On the above-described structures ST1 and ST2, a passivation film 111 can be provided to cover them.

The optical system OP (optical members) can be provided above the pixel region R1, and include a first planarization film 112, a color filter 113, a second planarization film 114, and microlenses 115. The planarization films 112 and 114 are films configured to form a flat upper surface so as to advantageously perform the formation process of members (such as the color filter 113 and the microlenses 115) to be formed later. The color filter 113 is provided corresponding to each pixel (of the photoelectric conversion portion 101) in accordance with, for example, Bayer arrangement. Each microlens 115 is provided corresponding to each pixel.

As described above, the solid-state image sensor I1 employs a so-called recess structure in which the upper surface of a portion including the wiring pattern (such as 104) and the interlayer insulation film (such as 103) provided on the substrate SUB is higher in a portion immediately above the peripheral region R2 than in a portion immediately above the pixel region R1. According to this structure, in the vicinity of the boundary K between the pixel region R1 and the peripheral region R2, a height difference on the upper surface of this structure is formed to be stepwise including the plurality of steps, but not formed locally. Therefore, according to this structure, for example, when a film is formed by spin coating in the formation process of the optical system OP or the like to be performed later, stripes and unevenness (so-called striations) that may occur in the film can be prevented.

The method for manufacturing the solid-state image sensor I1 will be described below with reference to FIGS. 2A to 2I. The solid-state image sensor I1 can be manufactured using a known semiconductor process.

First, as exemplified in FIG. 2A, the substrate SUB is prepared, and the structure ST1 is formed on the substrate SUB. As the substrate SUB, a semiconductor substrate such as a silicon substrate may be prepared by forming the respective elements (for example, the photoelectric conversion portions 101 and the transistors 102) on the substrate, or a substrate on which various kinds of elements are already formed may be prepared. In FIG. 2A, a structure which includes the wiring layers made of two layers, namely the wiring patterns 104 and 106 is illustrated as the structure ST1. However, the structure ST1 is not limited to this as long as it can be the base of the structure ST2 to be formed later. Then, a photoresist pattern 116a which has an opening in a region including the pixel region R1 is formed on the structure ST1.

Note that in the structure ST1, the interlayer insulation film may be made of an insulating material, and can be formed by, for example, a High Density Plasma CVD method. The interlayer insulation film can include, for example, an NSG (Non-doped Silicate Glass) film, a PSG (Phosphorus SG) film, and a BPSG (Boron Phosphorus SG) film. Metal materials such as Al, Cu, AlCu, TiN, and Ti are used for the wiring patterns of the respective wiring layers. Each wiring pattern may be formed by a single layer or a multilayer. In the description below, the same applies to the respective processes for forming the structure ST2.

As exemplified in FIG. 2B, the interlayer insulation film 107 in the structure ST1 is etched using the photoresist pattern 116a. This removes a part of the interlayer insulation film 107 above the pixel region R1. Note that the part can be removed to leave the interlayer insulation film 107 having a film thickness of, for example, 0.25 μm. Then, the photoresist pattern 116a is removed.

As exemplified in FIG. 2C, a metal member 108a is formed by depositing the metal material on the interlayer insulation film 107 in the structure ST1, and a photoresist pattern 116b is additionally formed.

As exemplified in FIG. 2D, the metal material 108a is then etched using the photoresist pattern 116b. This forms the wiring pattern 108 above the peripheral region R2. Then, the photoresist pattern 116b is removed.

As exemplified in FIG. 2E, the insulation member 109 is formed to cover the wiring pattern 108 and the structure ST1, and a photoresist pattern 116c is additionally formed. The distance from the boundary K to the end portion of the photoresist pattern 116c is larger than the distance from the boundary K to the end portion of the photoresist pattern 116b.

As exemplified in FIG. 2F, a part of the insulation member 109 is then removed using the photoresist pattern 116c. Note that the part can be removed to leave the insulation member 109 having a film thickness of, for example, 0.25 μm. The insulation member 109 functions as a protective film to protect the wiring pattern 108 in the subsequent formation process of the wiring pattern 110. Then, the photoresist pattern 116c is removed. The protective film has a convex portion formed by covering the steps between the upper surface of the wiring pattern 108 and that of the structure ST1. The side surface of the convex portion is located closer to the pixel region than the end of the first wiring pattern. That is, the distance from the boundary K to the side surface of the convex portion is smaller than the distance from the boundary K to the end of the first wiring pattern.

As exemplified in FIG. 2G, a metal member 110a is formed by depositing the metal material on the insulation member 109, and a photoresist pattern 116d is additionally formed. The distance from the boundary K to the end portion of the photoresist pattern 116d is larger than the distances from the boundary K to the end portions of the photoresist patterns 116b and 116c, respectively.

As exemplified in FIG. 2H, the metal member 110a is then etched using the photoresist pattern 116d. This forms the wiring pattern 110 on the convex portion formed by the steps between the upper surface of the wiring pattern 108 of the insulation member 109 and the upper surface of the structure ST1. The distance between the boundary K to the end portion of the wiring pattern 110 is larger than the distance between the boundary K to the end portion of the wiring pattern 108. Then, the photoresist pattern 116d is removed.

As described above, the structure ST2 can be formed. According to the above-described manufacturing method, since the wiring pattern 108 is covered by the insulation member 109, damage to the wiring pattern 108 in the respective steps is prevented. When the uppermost interlayer insulation film 107 in the structure ST1 is etched, the wiring pattern 108 is not used as an etching mask. As a result, the upper surface of the interlayer insulation film 107 is flat in the vicinity of the end of the wiring pattern 108. The vicinity of the end need at least include a region which extends from the end to the side of the pixel region R1, and may include the vicinity of the end outside the pixel region R1 in addition to the vicinity of the end inside the pixel region R1. Furthermore, since the wiring pattern 108 is not used as the etching mask, damage to the wiring pattern 108 can be reduced.

Note that in the structure ST2, the arrangement which includes the wiring layers made of two layers, namely the wiring patterns 108 and 110 is illustrated. However, the present invention is not limited to this arrangement, and also applies to a case where the arrangement includes three or more wiring layers.

Finally, as exemplified in FIG. 2I, the solid-state image sensor I1 is obtained by forming the passivation film 111 and the optical system OP as described above. The passivation film 111 and the respective members which make up the optical system OP can be deposited by spin coating. However, according to the above-described manufacturing method, the height difference on the upper surface is formed to be stepwise including the plurality of steps, but not formed locally. Therefore, the respective films can uniformly be formed.

As described above, the aforementioned recess structure is formed. The height difference on the upper surface of the structure in the vicinity of the boundary K is formed to be stepwise including the plurality of steps. According to the above-described manufacturing method, the individual sizes of the plurality of steps are small as compared to a case where a local step (for example, one large step) is formed. Furthermore, according to the above-described manufacturing method, additional steps can also be formed in the insulation member 109 between the wiring patterns 108 and 110. This is therefore advantageous in preventing a striation that may occur when forming a film by spin coating later. According to the above-described manufacturing method, since the wiring pattern 108 is covered by the insulation member 109 which functions as the protective film, damage to the wiring pattern 108 can be prevented. Accordingly, this embodiment is advantageous in improving the quality of a solid-state image sensor with a recess structure.

### Second Embodiment

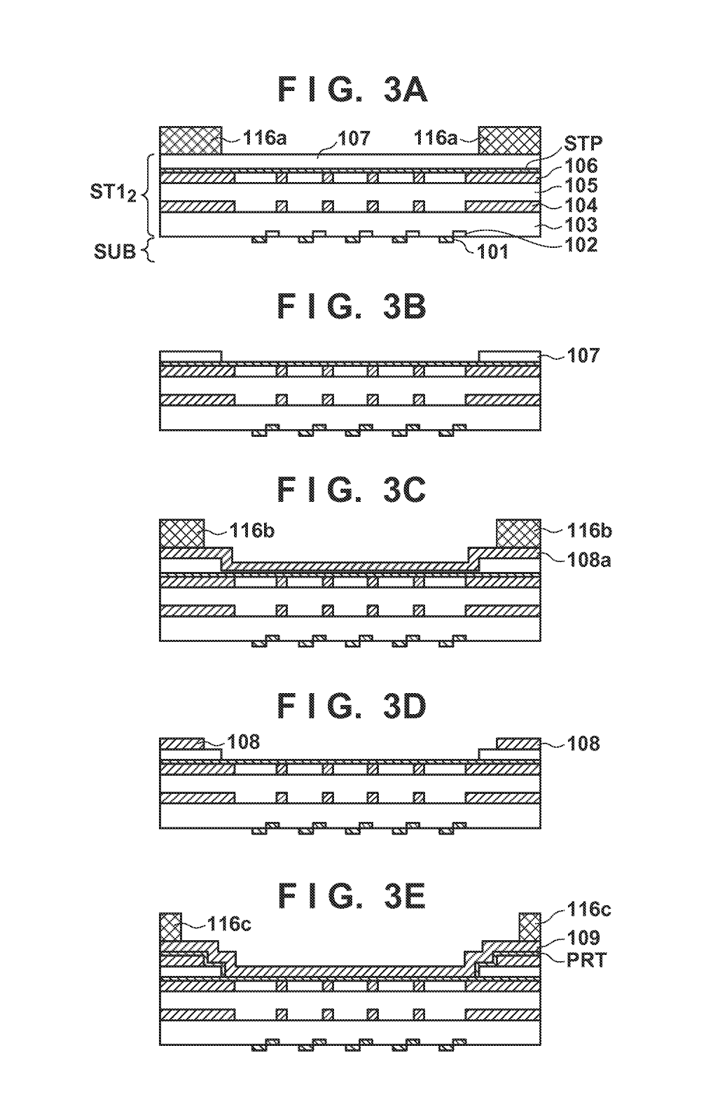

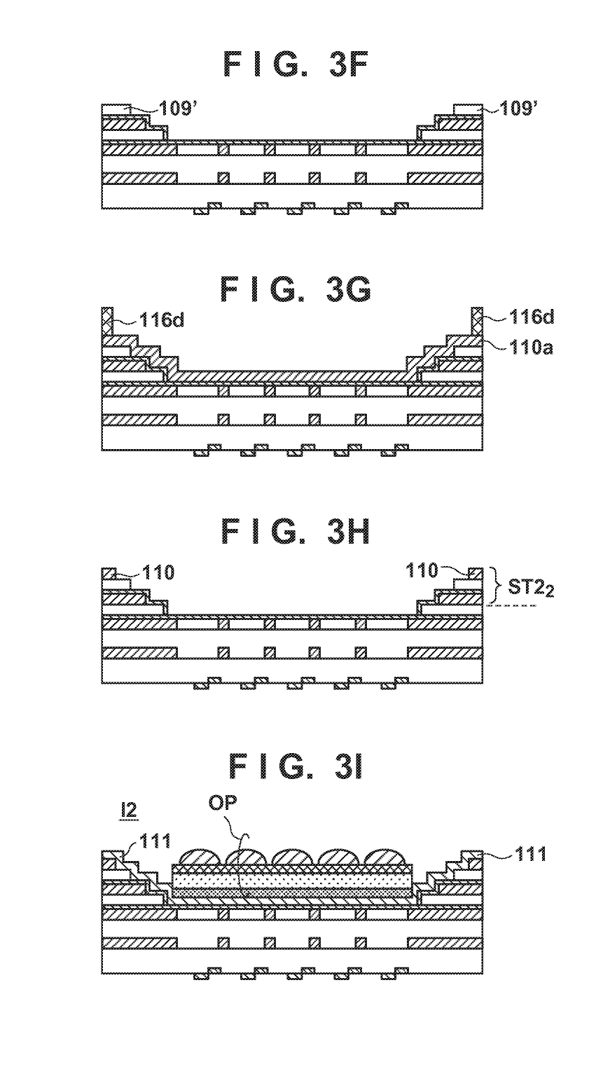

The second embodiment will be described with reference to FIGS. 3A to 3I. In the above-described first embodiment, the insulation member 109 which serves as the interlayer insulation film is formed as the protective film of the wiring pattern 108 in the formation process of the structure ST2. However, the present invention is not limited to this mode. The protective film and the interlayer insulation film may individually be formed as in this embodiment.

First, as exemplified in FIG. 3A, a substrate SUB is prepared, and a structure ST1₂ is formed on the substrate SUB. In this embodiment, the structure ST1₂ includes an etching stopper STP formed by using the same material as a protective film PRT (to be described later) under an uppermost interlayer insulation film 107 (between a wiring layer including a wiring pattern 106 and the interlayer insulation film 107). For example, silicon oxynitride (SiON) or silicon nitride (SiN) can be used for the etching stopper STP. Then, a photoresist pattern 116a which has an opening in a region including a pixel region R1 is formed on the structure ST1₂.

As exemplified in FIG. 3B, the interlayer insulation film 107 is then etched using the photoresist pattern 116a. This removes the upper portion of the interlayer insulation film 107 in the pixel region R1. Since the structure ST1₂ includes the etching stopper STP in this embodiment, the portion can be removed to expose the upper surface of the etching stopper STP. Then, the photoresist pattern 116a is removed.

As exemplified in FIG. 3C, a metal member 108a is formed by depositing a metal material on the interlayer insulation film 107 in the structure ST1₂, and a photoresist pattern 116b is additionally formed.

As exemplified in FIG. 3D, the metal material 108a is then etched using the photoresist pattern 116b. This forms a wiring pattern 108 above a peripheral region R2. Then, the photoresist pattern 116b is removed.

As exemplified in FIG. 3E, the protective film PRT is formed to cover the wiring pattern 108 and the structure ST1₂, an insulation member 109 is formed to cover the protective film PRT, and a photoresist pattern 116c is additionally formed. For example, silicon oxynitride (SiON) or silicon nitride (SiN) can be used for the protective film PRT. The protective film PRT functions as a protective film to protect the wiring pattern 108 in the subsequent formation process of a wiring pattern 110.

As exemplified in FIG. 3F, a part of the insulation member 109 is then removed using the photoresist pattern 116c, and an insulating pattern 109′ is formed. Then, the photoresist pattern 116c is removed.

As exemplified in FIG. 3G, a metal member 110a is formed by depositing the metal material on the insulating pattern 109′ and the protective film PRT, and a photoresist pattern 116d is additionally formed.

As exemplified in FIG. 3H, the metal member 110a is then etched using the photoresist pattern 116d. This forms the wiring pattern 110 on the insulating pattern 109′. The distance between a boundary K to the end portion of the wiring pattern 110 is larger than the distance between the boundary K to the end portion of the wiring pattern 108. Then, the photoresist pattern 116d is removed.

As described above, the structure ST2₂ can be formed. According to the above-described manufacturing method, since the wiring pattern 108 is covered by the protective film PRT, damage to the wiring pattern 108 in the respective steps is prevented. When the uppermost interlayer insulation film 107 in a structure ST1 is etched, the wiring pattern 108 is not used as an etching mask. As a result, the upper surface of the uppermost interlayer insulation film 107 in the structure ST1 is flat in the vicinity of the end of the wiring pattern 108 (at least in the region which extends from the end to the side of the pixel region R1).

Finally, as exemplified in FIG. 3I, a solid-state image sensor I2 is obtained by forming a passivation film 111 and an optical system OP as described above.

As described above, according to this embodiment as well, a stepwise recess structure in which there are a plurality of steps on an upper surface is formed as in the first embodiment.

According to the above-described manufacturing method, since the wiring pattern 108 is covered by the protective film PRT, damage to the wiring pattern 108 can be prevented. Accordingly, this embodiment is advantageous in improving the quality of a solid-state image sensor with a recess structure.

### Third Embodiment

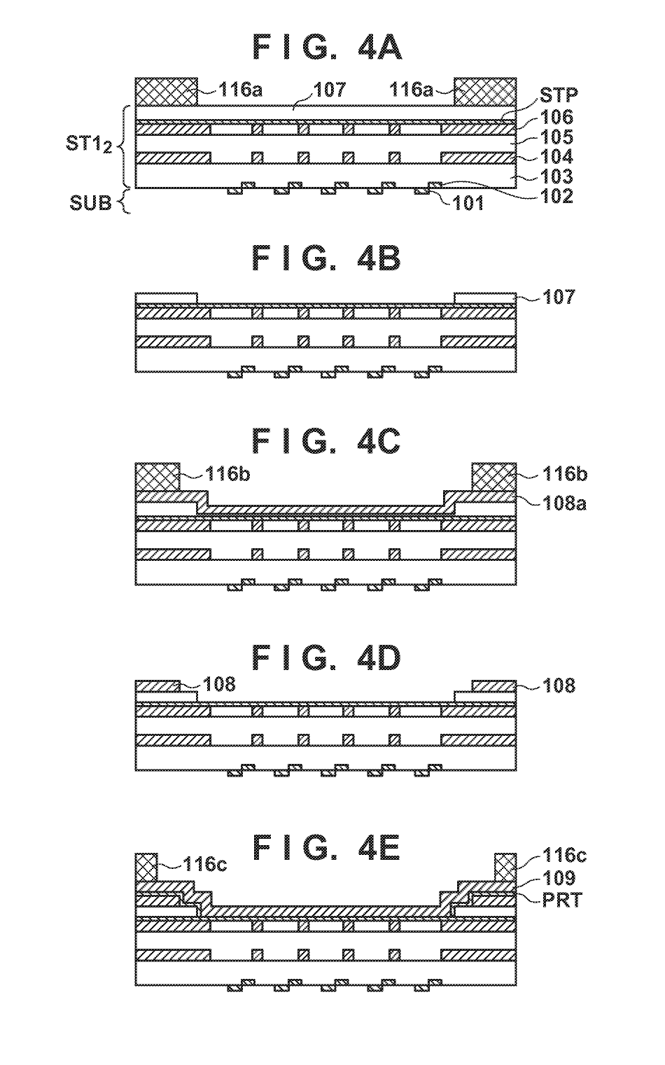

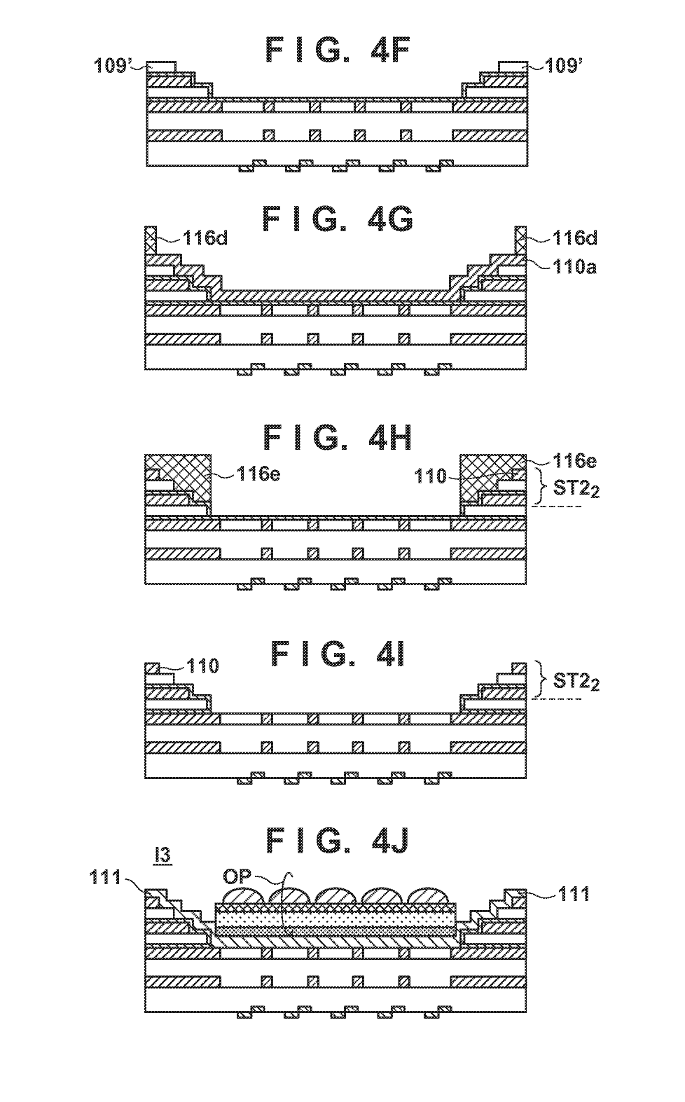

The third embodiment will be described with reference to FIGS. 4A to 4J. In the above-described second embodiment, the mode in which the etching stopper STP and the protective film PRT remain above the pixel region R1 has been exemplified. However, the present invention is not limited to this mode. After the etching stopper STP and the protective film PRT undergo a predetermined process, they may be removed as needed. FIGS. 4A to 4G are the same as FIGS. 3A to 3I, and a description thereof will be omitted.

As exemplified in FIG. 4H, a photoresist pattern 116e is additionally formed after forming a wiring pattern 110 on an insulating pattern 109′. The photoresist pattern 116e has an opening at least above a pixel region R1.

As exemplified in FIG. 4I, an etching stopper STP and a protective film PRT are then removed by etching using the photoresist pattern 116e. Note that this etching can be performed by setting a selectivity condition so that the etching rates of the etching stopper STP and the protective film PRT are higher than that of an interlayer insulation film.

Finally, as exemplified in FIG. 4J, a solid-state image sensor I3 is obtained by forming a passivation film 111 and an optical system OP as described above.

As described above, according to the this embodiment as well, a stepwise recess structure in which there are a plurality of steps on an upper surface is formed as in the first and the second embodiments. According to the above-described manufacturing method, the upper portion of the etching stopper STP and the protective film PRT in the pixel region R1 is removed before forming the optical system OP. Consequently, the distance between the optical system OP and a substrate SUB can be made smaller than those in the above-described respective embodiments. Furthermore, scattering of light that may occur in these respective layers can be prevented. Therefore, according to this embodiment, it is possible to improve the light sensitivity of the solid-state image sensor I3, in addition to obtaining the same effects as in the first and the second embodiments.

Note that in the third embodiment, the mode in which both of the etching stopper STP and the protective film PRT are removed using the same material for the etching stopper STP and the protective film PRT has been exemplified. However, the present invention is not limited to this mode. For example, different materials may be used for the etching stopper STP and the protective film PRT, and the protective film PRT may be removed while leaving the etching stopper STP in the step of FIG. 4I.

### Fourth Embodiment

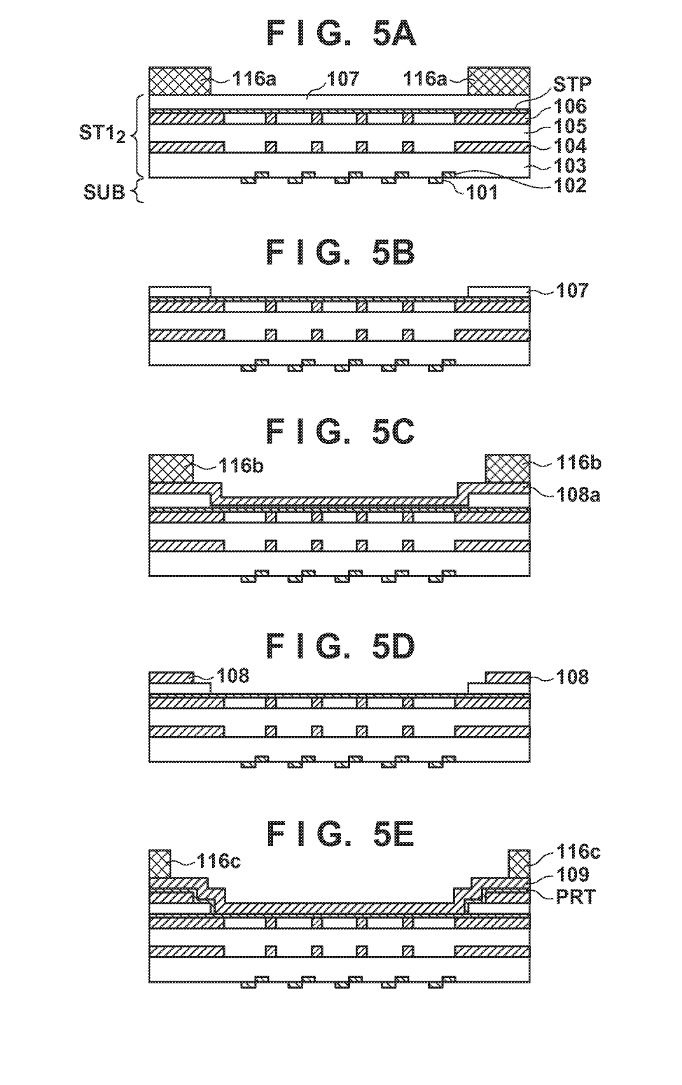

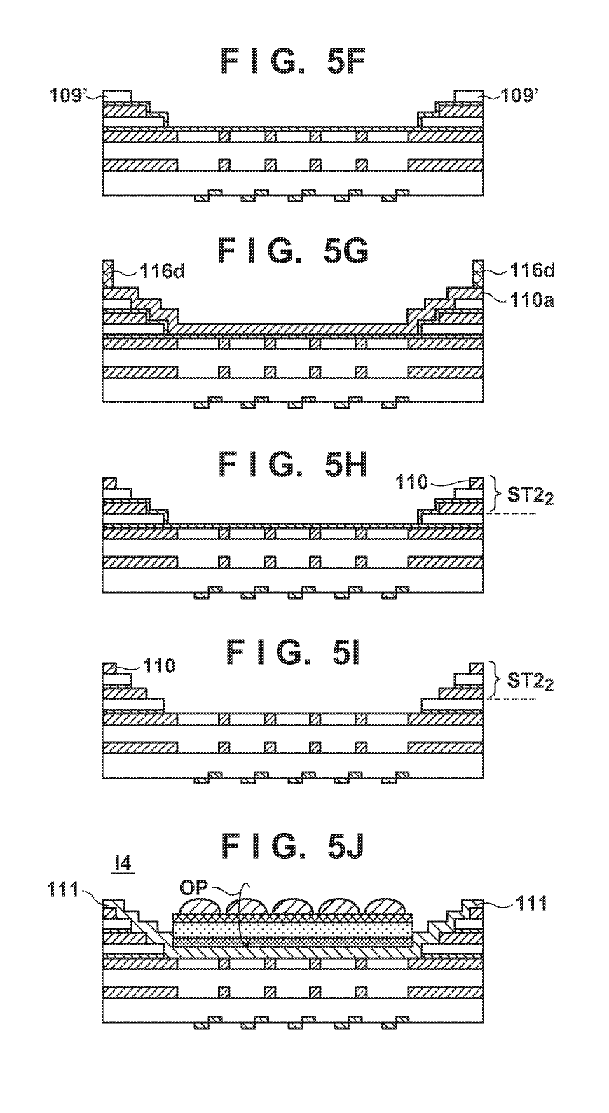

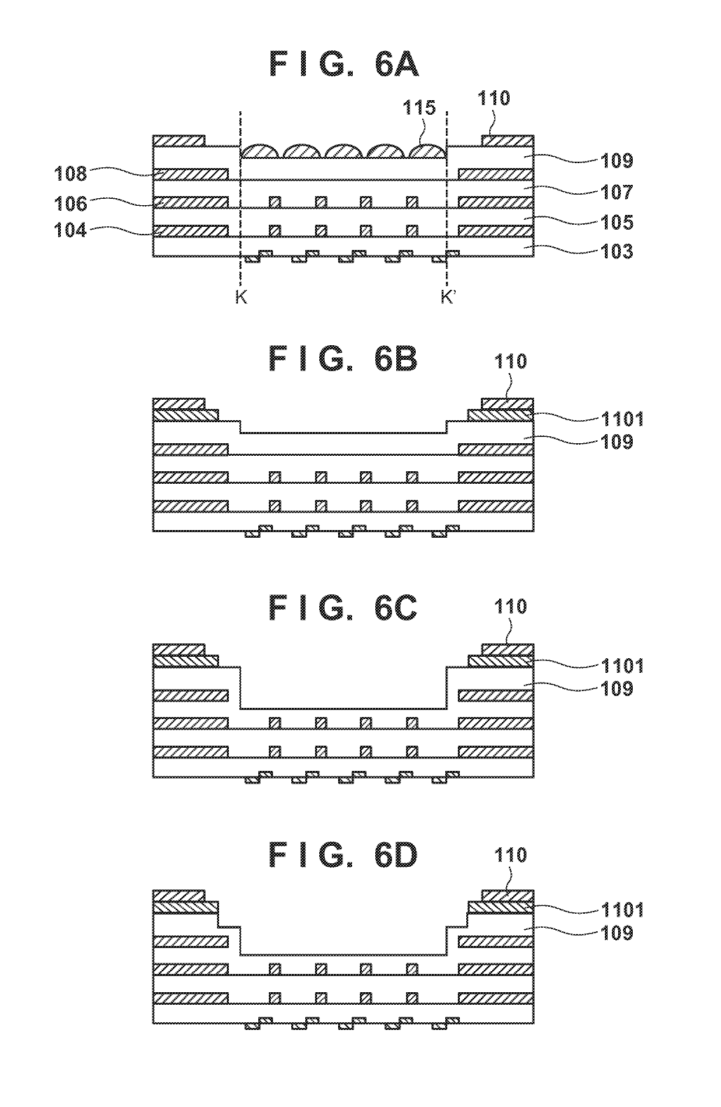

The fourth embodiment will be described with reference to FIGS. 5A to 5J. In the above-described third embodiment, the mode in which the etching stopper STP and the protective film PRT are removed by etching using the photoresist pattern 116e has been exemplified. However, the present invention is not limited to this mode. The etching stopper STP and the protective film PRT can be removed by another method. FIGS. 5A to 5G are the same as FIGS. 3A to 3I and FIGS. 4A to 4J, and a description thereof will be omitted.

After forming a wiring pattern 110 on an insulating pattern 109′ as exemplified in FIG. 5H, the exposed portions of an etching stopper STP and a protective film PRT are removed by etching as exemplified in FIG. 5I. This etching can be performed by setting a selectivity condition so that the etching rates of the etching stopper STP and the protective film PRT are higher than that of an interlayer insulation film.

Finally, as exemplified in FIG. 5J, a solid-state image sensor I4 is obtained by forming a passivation film 111 and an optical system OP as described above.

As described above, according to the this embodiment as well, a stepwise recess structure in which there are a plurality of steps on an upper surface is formed as in the first to the third embodiments. According to the above-described manufacturing method, the upper portion of the etching stopper STP and the protective film PRT in a pixel region R1 is removed before forming the optical system OP. Consequently, the distance between the optical system OP and a substrate SUB can be made smaller than those in the above-described respective embodiments. Therefore, according to this embodiment, it is possible to obtain the same effects as in the third embodiment.

### Fifth Embodiment

The fifth embodiment will be described with reference to FIG. 6A. In the fifth embodiment, an insulation member 109 is provided under a wiring pattern 110. In a planar view, the distance from the boundary K to the end portion of the wiring pattern 110 is larger than the distance from a boundary K to the end portion of the insulation member 109. Microlenses 115 are provided between two end portions of the insulation member 109 in FIG. 6A. In this arrangement as well, it is possible to form a stepwise recess structure in which there are a plurality of steps on an upper surface as in the first to the fourth embodiments.

### Sixth Embodiment

The sixth embodiment will be described with reference to FIG. 6B. Unlike the structure in the fifth embodiment, a protective film 1101 is additionally provided under a wiring pattern 110 in the sixth embodiment. In a planar view, the distance from a boundary K to the end portion of the protective film 1101 is larger than the distance from the boundary K to the end portion of an insulation member 109, and smaller than the distance from the boundary K to the end portion of the wiring pattern 110. In this arrangement as well, it is possible to form a stepwise recess structure in which there are a plurality of steps on an upper surface as in the first to the fifth embodiments.

### Seventh Embodiment

The seventh embodiment will be described with reference to FIG. 6C. Unlike the structure in the sixth embodiment, the parts of insulation members 109 and 107 are removed, and the end portions of the insulation members 109 and 107 are located in the same plane in the seventh embodiment. In this arrangement as well, it is possible to form a stepwise recess structure in which there are a plurality of steps on an upper surface as in the first to the sixth embodiments.

### Eighth Embodiment

The eighth embodiment will be described with reference to FIG. 6D. Unlike the structure in the seventh embodiment, the part of an insulation member 109 is further removed, and the insulation member 109 has two end portions whose distances from a boundary K are different in the eighth embodiment. In this arrangement as well, it is possible to form a stepwise recess structure in which there are a plurality of steps on an upper surface as in the first to the seventh embodiments.

The plurality of embodiments have been described above. However, the present invention is not limited to these. Changes and modifications can appropriately be made in accordance with objects, states, application purposes, functions, and other specifications, and the present invention can also be implemented by other embodiments.

(Imaging System)

In the above embodiments, the present invention has been described by exemplifying a solid-state image sensor included in an imaging system represented by a camera or the like. The concept of the imaging system includes not only apparatuses primarily aiming at shooting but also apparatuses (for example, personal computer and portable terminal) secondarily having a shooting function. The imaging system can include the solid-state image sensor according to the present invention exemplified in the above embodiments, and a processor that processes a signal output from the solid-state image sensor. The processor can include, for example, an A/D converter, and a processor that processes digital data output from the A/D converter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-193486, filed Sep. 18, 2013, which is hereby incorporated by reference herein in its entirety.

What is claimed is:

1. A method for manufacturing a solid-state image sensor, comprising:
preparing a substrate including a pixel region where a plurality of pixels are provided and a peripheral region located outside the pixel region;
forming a structure including a wiring layer and an interlayer insulation film on the pixel region and the peripheral region of the substrate;
forming a first wiring pattern only on the structure located in the peripheral region;
forming a protective film covering the first wiring pattern and the structure;
forming a second wiring pattern on a convex portion of the protective film, the convex portion formed by steps between an upper surface of the first wiring pattern and an upper surface of the structure, so that an end of the second wiring pattern is located away from the pixel region than an end of the first wiring pattern in a state in which the protective film covers the first wiring pattern; and
forming an optical member on the structure of the pixel region.

2. The method according to claim 1, wherein after the forming the second wiring pattern, the upper surface of the structure is flat at least from above the pixel region to the end of the first wiring pattern.

3. The method according to claim 1, further comprising, after the forming the protective film and before the forming the second wiring pattern, forming an insulating pattern on the convex portion of the protective film so that an end of the insulting pattern is located away from the pixel region than the end of the first wiring pattern by forming, on the protective film, an insulation member which is a different material from the protective film, and then etching the insulation member, wherein the etching in the forming the insulating pattern is performed on a condition that an etching rate of the protective film is lower than an etching rate of the insulation member.

4. The method according to claim 3, wherein in the forming the second wiring pattern, the second wiring pattern is formed so that an end of the second wiring pattern is located away from the pixel region than the end of the insulating pattern.

5. The method according to claim 3, further comprising, after the forming the second wiring pattern and before the forming the optical member, removing a first portion of the protective film above the pixel region.

6. The method according to claim 3, further comprising, after the forming the second wiring pattern and before the forming the optical member, removing a second portion of the protective film which is exposed by etching, wherein the etching in the removing the second portion is performed on a condition that the etching rate of the protective film is higher than the etching rate of the insulation member.

7. The method according to claim 1, further comprising, after the forming the structure and before the forming the first wiring pattern, removing a third portion of an uppermost interlayer insulation film in the structure above the pixel region.

8. The method according to claim 7, wherein the structure includes an etching stopper under the uppermost interlayer insulation film in the structure, and the removing the third portion is performed to expose an upper surface of the etching stopper.

9. The method according to claim 1, further comprising, after the forming the second wiring pattern and before the forming the optical member, forming a passivation film covering the first wiring pattern, the second wiring pattern, and the protective film.

10. The method according to claim 1, wherein in the forming the protective film, the first wiring pattern is not used as an etching mask.

11. A solid-state image sensor comprising:
a substrate including a pixel region where a plurality of pixels are provided and a peripheral region located outside the pixel region;
a structure arranged on the pixel region and the peripheral region of the substrate, and including a wiring layer and an interlayer insulation film;
a first wiring pattern arranged on the structure in the peripheral region, and not arranged on the structure in the pixel region;
a second wiring pattern arranged on a protective film on the first wiring pattern, so that an end of the second wiring pattern is located to be away from the pixel region than an end of the first wiring pattern; and
an optical member arranged on the structure and the pixel region, and provided to correspond to the plurality of pixels;
wherein an upper surface of the structure is flat at least from above the pixel region to the end of the first wiring pattern.

12. A solid-state image sensor comprising:
a substrate including a pixel region where a plurality of pixels are provided and a peripheral region located outside the pixel region;
a structure arranged on the pixel region and the peripheral region of the substrate, and including a wiring layer and an interlayer insulation film;
a first wiring pattern arranged on the structure in the peripheral region, and not arranged on the structure in the pixel region;
a second wiring pattern arranged on a protective film on the first wiring pattern, so that an end of the second wiring pattern is located to be away from the pixel region than an end of the first wiring pattern; and
an optical system arranged on the structure and the pixel region, and provided to correspond to the plurality of pixels;
wherein a side surface of the end of the first wiring pattern is covered by the protective film,
the protective film has a convex portion formed by an upper surface of the first wiring pattern and an upper surface of the structure, and
a side surface of the convex portion of the protective film is located closer to the pixel region than the end of the first wiring pattern.

13. A camera comprising:
a solid-state image sensor of claim 11; and
a processor configured to process a signal from the solid-state image sensor.
